(19) United States
(12) Patent Application Publication
(10) Pub. No.: US 2012/0280429 A1
(43) Pub. Date: Nov. 8, 2012

(54) APPARATUS AND METHOD FOR PRODUCING A MULTICRYSTALLINE MATERIAL HAVING LARGE GRAIN SIZES

(75) Inventors: Bhuvaragasamy Ganesan Ravi, Nashua, NH (US); Santhana Raghavan Parthasarathy, Nashua, NH (US); David Lackey, Merrimack, NH (US); Andre Andrukhiv, Hollis, NH (US); David Lyttle, Amherst, NH (US); Bala Bathey, Tewksbury, MA (US); Carl Chartier, Manchester, NH (US)

(73) Assignee: GT SOLAR, INC., Merrimack, NH (US)

(21) Appl. No.: 13/098,989

(22) Filed: May 2, 2011

(51) Int. Cl. C30B 28/06

(52) U.S. Cl. 264/332; 425/446

(57) ABSTRACT

A crystal growth apparatus is disclosed comprising a crucible, optionally contained within a crucible box, on a crucible support block, wherein the bottom of the crucible, the bottom plate of the crucible box, if used, and/or the crucible support block comprise at least one cavity configured to circulate at least one coolant therein. Also disclosed is a method of preparing a crystalline material using the disclosed crystal growth apparatus as well as the resulting crystalline material, having larger overall grain sizes.

### BACKGROUND OF THE INVENTION

1. Field of the Invention

The present invention relates to an apparatus and method for producing a crystalline material having large crystal grain sizes.

2. Description of the Related Art

Crystal growth apparatuses or furnaces, such as directional solidification systems (DSS) and heat exchanger method (HEM) furnaces, involve the melting and controlled resolidification of a feedstock material, such as silicon, in a crucible to produce an ingot. Production of a solidified ingot from molten feedstock occurs in several identifiable steps over many hours. For example, to produce a silicon ingot by the DSS method, solid silicon feedstock is provided in a crucible, often contained in a graphite crucible box, and placed into the hot zone of a DSS furnace. The feedstock is then heated to form a liquid feedstock melt, and the furnace temperature, which is well above the silicon melting temperature of 1412° C., is maintained for several hours to ensure complete melting. Once fully melted, heat is removed from the melted feedstock, often by applying a temperature gradient in the hot zone, in order to directionally solidify the melt and form a silicon ingot. By controlling how the melt solidifies, an ingot having greater purity than the starting feedstock material can be achieved, which can then be used in a variety of high end applications, such as in the semiconductor and photovoltaic industries.

In a typical directional solidification of silicon feedstock, the resulting solidified silicon ingot is generally multicrystalline, having random small crystal grain sizes and orientations. For example, in general, a DSS-produced multicrystalline silicon ingot has randomly oriented crystal grains of sizes less than or equal to 500 mm², and rarely grains of larger than 1000 mm² are observed. It has been found that these randomly oriented small grain boundaries act as recombination centers of light induced electrons and holes, and these defects have been shown to reduce the efficiency of solar cells produced from multicrystalline silicon.

By comparison, silicon ingots produced having substantially larger grains or a monocrystalline structure have been found to have increased solar cell efficiencies. However, methods to prepare such materials are typically slow, difficult and expensive. For example, to produce a monocrystalline silicon ingot using either a DSS or HEM process, a solid seed of monocrystalline silicon is placed in the bottom of a crucible along with the silicon feedstock, and, if the seed is maintained after the feedstock has fully melted, crystallization of the melt occurs corresponding to the crystal orientation of the monocrystalline seed. However, for such a process, it is often difficult and time consuming to prevent the seed from melting, and, for a HEM furnace, additional equipment and controls are required. Furthermore, the resulting silicon ingots typically have only a moderate yield of monocrystalline material throughout the final silicon ingot. Low yields results in significant loss of usable material, increasing the cost of the process and the desired final product.

Therefore, there is a need in the industry for a crystal growth apparatus and method to produce a crystalline material, such as multicrystalline silicon, having large grain sizes and correspondingly reduced grain boundaries economically and under controlled conditions, in order to provide cells having higher overall efficiencies.

### SUMMARY OF THE INVENTION

The present invention relates to a crystal growth apparatus comprising a hot zone surrounded by insulation and a crucible, optionally contained within a crucible box, on a crucible support block in the hot zone. At least one cavity is provided in the bottom of the crucible, in the bottom of the optional crucible box, and/or in the crucible support block. In one embodiment, the crucible is contained in a crucible box having a bottom plate in thermal communication, preferably in thermal contact, with the crucible support block, and the crucible has a bottom in thermal communication, preferably thermal contact, with the bottom plate of the crucible box. The crucible support block, the bottom plate of the crucible box, or both the crucible support block and the bottom plate of the crucible box comprise at least one cavity configured to circulate at least one coolant therein. In another embodiment, the crucible is on the crucible support block and has a bottom in thermal communication, preferably thermal contact, with the crucible support block. The crucible support block, the bottom of the crucible, or both the crucible support block and the bottom of the crucible comprise at least one cavity configured to circulate at least one coolant. For this embodiment, preferably the crucible is silicon carbide, silicon nitride, or composites of silicon carbide or silicon nitride with silica.

The present invention further relates to a method of producing a crystalline material comprising the steps of placing a crucible containing solid feedstock, optionally contained in a crucible box, onto a crucible support block in a hot zone of a crystal growth apparatus; heating the solid feedstock in the crucible to form a liquid feedstock melt; and circulating at least one coolant through at least one cavity in the bottom of the crucible, in the bottom of the optional crucible box, and/or in the crucible support block. In one embodiment, the method comprises the steps of: i) placing a crucible contained in a crucible box onto a crucible support block in the hot zone, the crucible box having a bottom plate in thermal communication, preferably thermal contact, with the crucible support block and the crucible containing solid feedstock and having a bottom in thermal communication, preferably thermal contact, with the bottom plate of the crucible box; ii) heating the solid feedstock in the crucible to form a liquid feedstock melt; iii) circulating at least one coolant through at least one cavity in the crucible support block, the bottom plate of the crucible box, or both the crucible support block and the bottom plate of the crucible box; and iv) removing heat from the hot zone to form the crystalline material. In another embodiment, the method comprises the steps of: i) placing a crucible onto a crucible support block in the hot zone, the crucible containing solid feedstock and having a bottom in thermal communication, preferably thermal contact, with the crucible support block; ii) heating the solid feedstock in the crucible to form a liquid feedstock melt; iii) circulating at least one coolant through at least one cavity in the crucible, the crucible support block, or both the crucible and the crucible support block and the bottom plate of the crucible box; and iv) removing heat from the hot zone to form the crystalline material.

It is to be understood that both the foregoing general description and the following detailed description are exemplary and explanatory only and are intended to provide further explanation of the present invention, as claimed.

### BRIEF DESCRIPTION OF THE DRAWINGS

FIG. 1 is a cross-sectional view of an embodiment of the crystal growth apparatus of the present invention. FIG. 2, FIG. 3, and FIG. 4 are expanded views of insert B from FIG. 1 showing additional features of embodiments of the crystal growth apparatus of the present invention.

FIG. 5, FIG. 6, FIG. 6a, FIG. 7, and FIG. 8 are views of cavities used in various embodiments of the crystal growth apparatus of the present invention.

FIG. 9 is a portion of a cross-section of a crystalline material prepared using an embodiment of the method of the present invention, and

FIG. 10 is a portion of a cross-section of a crystalline material prepared using a comparative method.

FIG. 11 is a graph showing the grain area distributions determined for the crystalline materials in FIG. 9 and FIG. 10.

### DETAILED DESCRIPTION OF THE INVENTION

The present invention relates to a crystal growth apparatus and method of producing a crystalline material.

The crystal growth apparatus of the present invention is a furnace, in particular a high-temperature furnace, capable of heating and melting a solid feedstock, such as silicon, at temperatures generally greater than about 1000° C. and subsequently promoting resolidification of the resulting melted feedstock material to form a crystalline material, such as a multicrystalline silicon ingot. For example, the crystal growth apparatus can be a directional solidification system (DSS) crystal growth furnace. Preferably, the solid feedstock does not contain a monocrystalline silicon seed, although one can be used if a crystalline material that is monocrystalline or substantially monocrystalline is desired.

The crystal growth apparatus of the present invention comprises an outer furnace chamber or shell and an interior hot zone within the furnace shell. The furnace shell can be any known in the art used for high temperature crystallization furnaces, including a stainless steel shell comprising an outer wall and an inner wall defining a cooling channel for circulation of a cooling fluid, such as water. The hot zone of the crystal growth apparatus is an interior region within the furnace shell in which heat can be provided and controlled to melt and resolidify a feedstock material. The hot zone is surrounded by and defined by insulation, which can be any material known in the art that possesses low thermal conductivity and is capable of withstanding the temperatures and conditions in a high temperature crystal growth furnace. For example, the hot zone can be surrounded by insulation of graphite. The shape and dimension of the hot zone can be formed by a plurality of insulation panels which can either be stationary or mobile. For example, the hot zone may be formed of top, side, and bottom insulation panels, with the top and side insulation panels configured to move vertically relative to a crucible placed within the hot zone.

The hot zone further comprises a crucible, optionally within a crucible box, atop a crucible support block, and further comprises at least one cavity in the bottom of the crucible, in the bottom of the optional crucible box, and/or in the crucible support block, which will be described in more detail below. The crucible can be made of various heat resistant materials, for example, quartz (silica), graphite, silicon carbide, silicon nitride, composites of silicon carbon or silicon nitride with silica, pyrolytic boron nitride, alumina, or zirconia and, optionally, may be coated, such as with silicon nitride, to prevent cracking of the ingot after solidification. The crucible can also have a variety of different shapes having at least one side and a bottom, including, for example, cylindrical, cubic or cuboid (having a square cross-section), or tapered. Preferably, when the feedstock is silicon, the crucible is made of silica and has a cube or cuboid shape.

The crucible can optionally be contained within a crucible box, which provides support and rigidity for the sides and bottom of the crucible and is particularly preferred for crucibles made of materials that are either prone to damage, cracking, or softening, especially when heated. For example, a crucible box is preferred for a silica crucible but may be unnecessary for a crucible made of silicon carbide, silicon nitride, or composites of silicon carbide or silicon nitride with silica. The crucible box can be made of various heat resistant materials, such as graphite, and typically comprises at least one side plate and a bottom plate, optionally further comprising a lid. For example, for a cube or cuboid-shaped crucible, the crucible box is preferably also in the shape of a cube or cuboid, having four walls and a bottom plate, with an optional lid.

The crucible and optional crucible box are provided on top of a crucible support block within the hot zone, and, as such, are in thermal communication with each other so that heat can be conducted from one to the other, preferably by direct thermal contact. The crucible support block can be raised on a plurality of pedestals in order to place the crucible into a central position in the crystal growth apparatus. The crucible support block can be made of any heat resistant material, such as graphite, and is preferably a similar material to the crucible box, if used.

The hot zone can also comprise at least one heating system, such as multiple heating elements to provide heat to melt a solid feedstock placed in the crucible. For example, the hot zone can comprise a top heating element, positioned horizontally in the upper region of the hot zone above the crucible, and at least one side heating element positioned vertically below the top heating element and along the sides of the hot zone and the crucible. The temperature in the hot zone may be controlled by regulating the power provided to the various heating elements.

As noted above, the hot zone further comprises at least one cavity in the bottom of the crucible, in the bottom of the optional crucible box, in the crucible support block, or any combination of these. The cavity is configured to contain and circulate at least one coolant within it. The coolant is any material capable of flowing through the cavity and removing heat from beneath a crucible containing a liquid feedstock melt formed in the crucible. The coolant can be a gas or a mixture of gases, such as argon or helium, or can be a liquid, such as water, or a mixture of liquids. In one embodiment of the present invention, the crystal growth apparatus comprises a crucible contained in a crucible box on a crucible support block in the hot zone. The crucible box has a bottom plate in thermal contact with the crucible support block, and the crucible has a bottom in thermal contact with the bottom plate of the crucible box. The crucible support block, the bottom plate of the crucible box, or both the crucible support block and the bottom plate of the crucible box comprise at least one cavity configured to circulate the coolant therein. In another embodiment of the present invention, the crystal growth apparatus comprises a crucible on a crucible support block in the hot zone, the crucible having a bottom in thermal contact with the crucible support block, and the crucible support block, the bottom of the crucible, or both the crucible support block and the bottom of the crucible comprise at least one cavity configured to circulate the coolant therein. For both embodiments, the cavity preferably has a separate coolant inlet and outlet, which allows the coolant to enter the cavity, circulate within the cavity to cool the liquid feedstock melt in the crucible from below, and exit the cavity. For gaseous coolants, the coolant can be exhausted into the crystal growth apparatus, particular into the hot zone.

The cavity can have a variety of shapes and can be provided using any method known in the art, including, for example, by drilling or otherwise cutting out a portion of the crucible bottom, the optional crucible box, and/or the crucible support block, or by preforming these components with the cavity in place. Also, a cavity may be formed in one of the components and an appropriately shaped insert may be provided in the cavity to create the desired final shape. Preferably, the cavity has a centrosymmetric cross-sectional shape, having a rotational axis of symmetry perpendicular to the center of the cavity. For example, the cavity can be square, rectangular, oval, or circular in cross-sectional shape in a direction parallel to the bottom of the crucible. Also, the cavity can form a spiral path in a direction parallel to the crucible bottom, with the path having either a constant or varying thickness from the inlet to the outlet. In addition, the cavity can have either a concave or convex cross-sectional shape in a direction perpendicular to the crucible bottom.

Furthermore, the cavity can be provided anywhere within the bottom of the crucible, in the bottom of the optional crucible box, and/or in the crucible support block. For example, the cavity can be centered horizontally within these components and is preferably provided beneath the center of the crucible. In addition, the crucible, crucible box, or crucible support block may each comprise one or more cavities. For example, a square-shaped crucible support block may comprise one cavity in the center or may comprise a center cavity along with additional cavities in each of the corners. Also, the cavity can be vertically in the center of the component or can be either in the top surface or bottom surface and thus in contact with the component above or below it. Preferably, the cavity is provided in a component to be as close to the feedstock in the crucible as possible. For example, the cavity can be along the surface of the crucible block in thermal contact with the crucible bottom or the bottom plate of the optional crucible box. Also, two adjacent components may each comprise a cavity that, together, forms a larger cavity for circulating the coolant. For example, the top surface of the crucible support block may comprise a shallow circular cavity and the bottom surface of the bottom plate of the crucible box may also comprise a shallow circular cavity, together forming a larger cylindrical cavity for circulating the coolant. Other combinations will be recognized by one of ordinary skill in the art.

The thickness of the cavity can vary depending on thickness of the component in which it is provided and the type of material used. In general, a cavity provided in the bottom of the crucible or the bottom of the crucible box, each of which are typically relatively thin, would be thinner and have a smaller diameter than a cavity provided in the crucible support block, which is typically much thicker and more rigid. Also, components made of materials such as graphite or silicon carbide can support a wider and larger cavity. For example, for the embodiments of the present invention in which the cavity is in the bottom of the crucible, and the crucible is made of silica, the cavity would be relatively small and thin in order to avoid causing the crucible to crack and cause a spill. For silicon carbide crucibles, the cavity may be relatively larger and greater in thickness. Also, cavities placed within the bottom plate of the crucible box made of graphite, if used, would need to be of a size and diameter appropriate to support the weight of the feedstock in the crucible, which is particularly important when large loads, such as greater than 650 kg, are used. Cavities provided in the crucible support block, which are typically larger and made of graphite, can be larger and thicker without compromising the integrity of the block. Desired cavity sizes for specific crucibles, curable boxes, and crucible support blocks made of specific materials would be readily determined by one of ordinary skill in the art without undue experimentation.

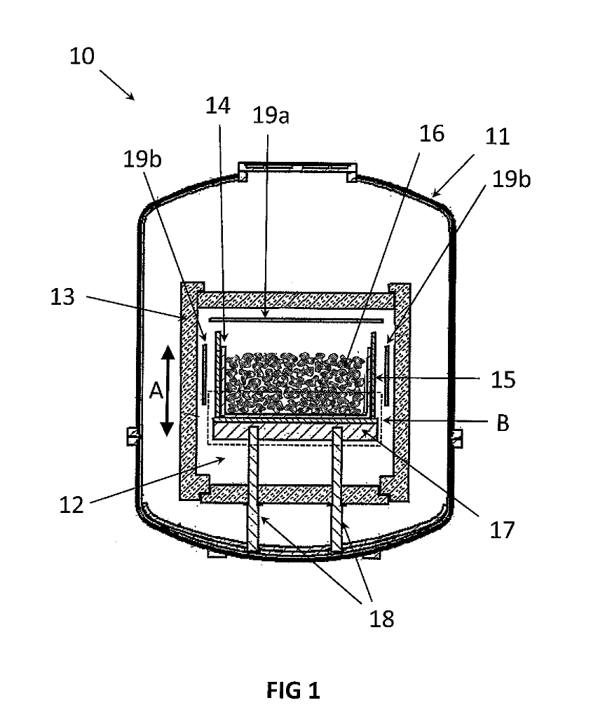

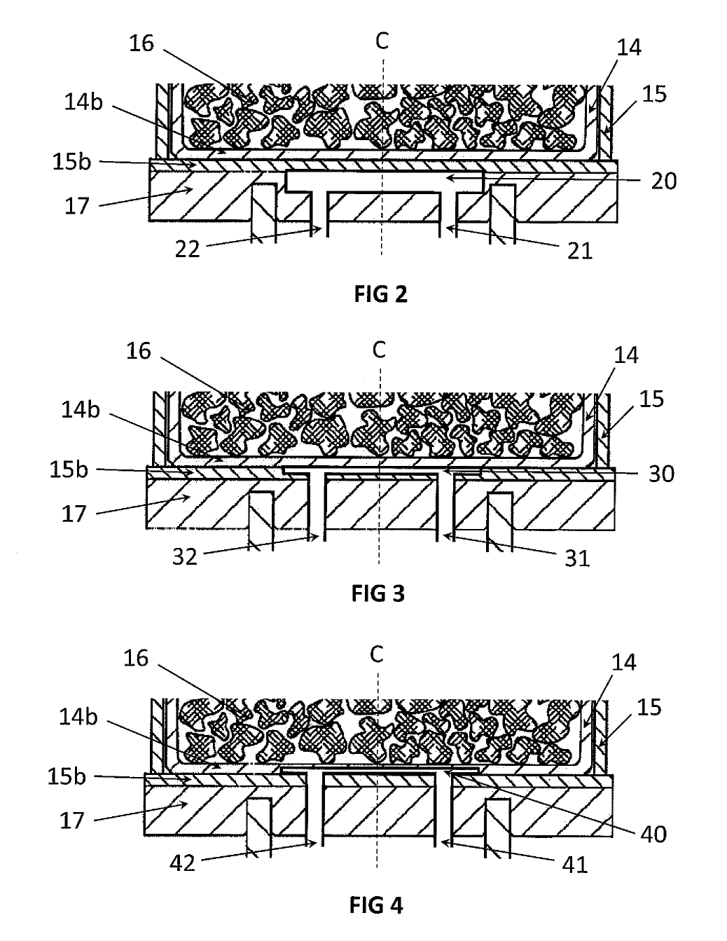

FIG. 1 is a cross-sectional view of an embodiment of the crystal growth apparatus of the present invention. However, it should be apparent to those skilled in the art that these are merely illustrative in nature and not limiting, being presented by way of example only. Numerous modifications and other embodiments are within the scope of one of ordinary skill in the art and are contemplated as falling within the scope of the present invention. In addition, those skilled in the art should appreciate that the specific configurations are exemplary and that actual configurations will depend on the specific system. Those skilled in the art will also be able to recognize and identify equivalents to the specific elements shown, using no more than routine experimentation.

The crystal growth apparatus 10 shown in FIG. 1 comprises a furnace shell 11 and hot zone 12 within furnace shell 11 surrounded and defined by insulation 13. Crucible 14 within crucible box 15 containing feedstock 16 is provided in hot zone 12 atop crucible support block 17 raised on pedestals 18. Hot zone 12 further includes a heating system comprising top heater 19a and two side heaters 19b. Insulation cage 13 is movable vertically, as shown by arrow A, and this is the primary means for removing heat from the hot zone of crystal growth apparatus 10, which exposes hot zone 12 and the components contained therein to outer chamber 11, which is cooled using a cooling medium such as water.

Hot zone 12 of crystal growth apparatus 10 further comprises a cavity 20, 30, and 40 in crucible support block 17, in the bottom plate 15a of crucible box 15, or in the bottom 14b of crucible 14, as shown in FIG. 2, FIG. 3, and FIG. 4 respectively, which are expanded views of section B highlighted in FIG. 1. As shown in each of these figures, the bottom of the crucible 14b is in thermal contact with the bottom plate of the crucible box 15b, which is further in thermal contact with crucible support block 17, and cavity 20, 30, and 40 are positioned under the center C of crucible 14 and feedstock 16 contained therein. Cavity 20, 30, and 40 further include a coolant inlet 21, 31, and 41 and a coolant outlet 22, 32, and 42 respectively, which can be used interchangeably.

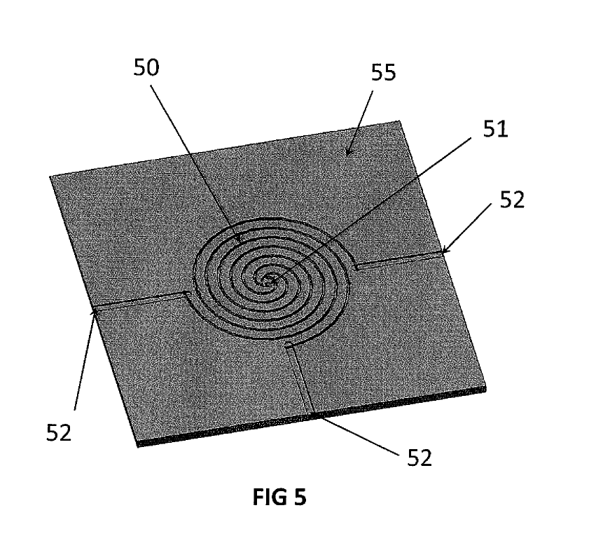

FIG. 5, FIG. 6, FIG. 6a, FIG. 7 and FIG. 8 each show specific examples of cavities that can be used in the crystal growth apparatus of the present invention. In particular, FIG. 5 is a schematic view of a bottom plate of a crucible box 55 having a spiral cavity 50, with a coolant gas inlet 51 and three coolant gas outlets 52. As can be seen, spiral cavity 50 is in the upper surface of the crucible box bottom plate and thus would be in direct thermal contact with the bottom of a crucible placed upon it. FIG. 6 is a schematic view of a crucible support block 67 having a cylindrical cavity 60 forming a circular opening 63 centered horizontally in the top surface, which would be in direct thermal contact with either the bottom plate of a crucible box or the bottom of a crucible placed upon it. FIG. 6a is another view of this crucible support block, as a cross-section along a diagonal. Cavity 60 has one coolant inlet 61 along with four coolant outlets 62 (three are visible in FIG. 6 and two are visible in FIG. 6a). FIG. 7 and FIG. 8 are cross-sectional views of a convex and a concave shaped cavity insert respectively, either of which can be placed into a cylindrical cavity similar to that in FIG. 6a, lining up coolant inlets (71 or 81 with 61) and coolant outlets (72 or 82 with 62) to create the desired concave or convex cavity shape.

The crystal growth apparatus of the present invention can be used in a method for preparing a crystalline material, such as a multicrystalline silicon ingot, from a solid feedstock, such as silicon. Thus, the present invention further relates to a method of preparing a crystalline material. The method comprises the steps of placing a crucible containing solid feedstock, optionally contained within a crucible box, onto a crucible support block in a hot zone of a crystal growth apparatus, and heating the solid feedstock in the crucible to form a liquid feedstock melt. Preferably, the crucible contains at least one solid feedstock and no monocrystalline seed. Once the solid feedstock is fully melted, the method further comprises the steps of circulating at least one coolant through at least one cavity in the bottom of the crucible, the bottom plate of the crucible box, and/or the crucible support block, and removing heat from the hot zone to form the crystalline material. Coolant circulation can be prior to or simultaneous with the beginning of heat removal. The crucible, optional crucible box, crucible support block, and cavity can be any of those described above. In one embodiment of the method, a crucible contained in a crucible box is placed onto a crucible support block, the crucible box having a bottom plate in thermal contact with the crucible support block and the crucible containing solid feedstock and having a bottom in thermal contact with the bottom plate of the crucible box. After heating the solid feedstock in the crucible and completely melting to form a liquid feedstock melt, at least one coolant is circulated through at least one cavity in the crucible support block, the bottom plate of the crucible box, or both the crucible support block and the bottom plate of the crucible box, and heat is removed from the hot zone. In another embodiment of the method, a crucible is placed onto a crucible support block, the crucible containing solid feedstock and having a bottom in thermal contact with the crucible support block, and the solid feedstock is heated in the crucible and fully melted to form a liquid feedstock melt. At least one coolant is circulated through at least one cavity in the crucible, the crucible support block, or both the crucible and the crucible support block and heat is removed from the hot zone to form the crystalline material.

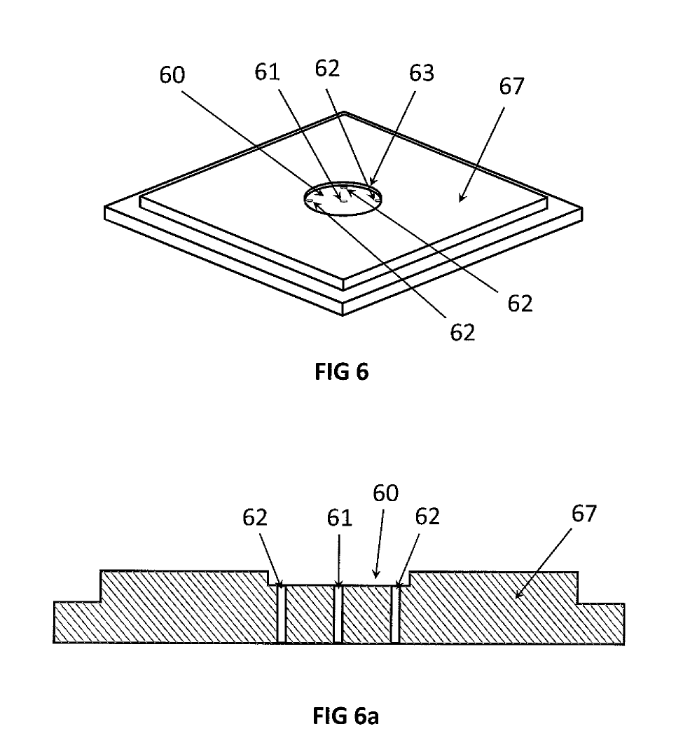

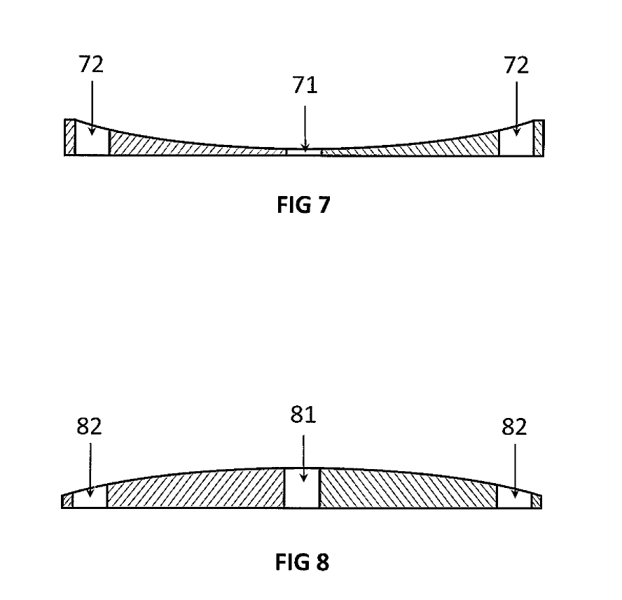

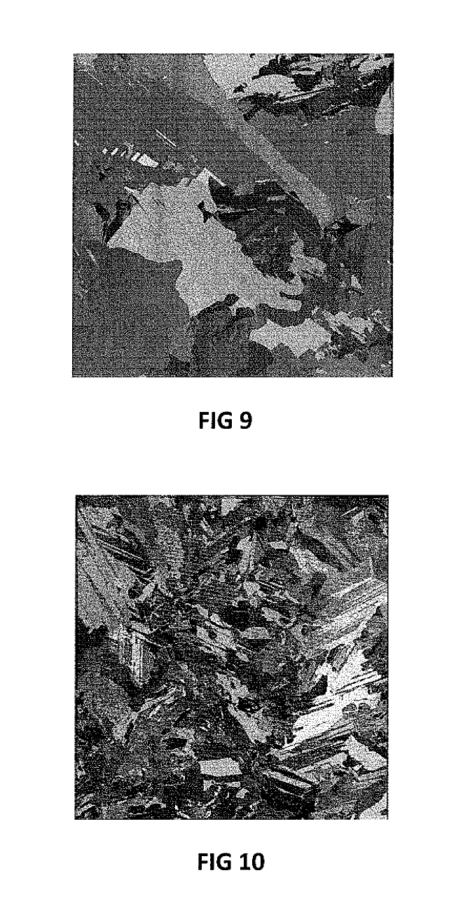

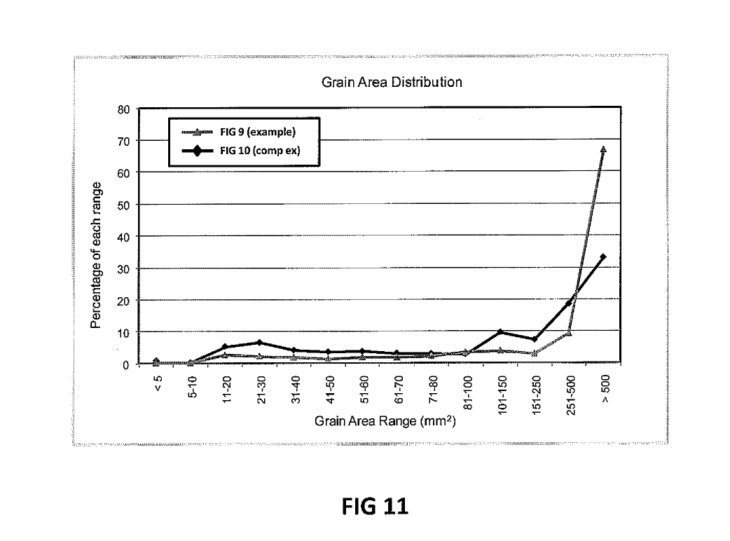

It has been found that the crystalline material produced by the method and apparatus of the present invention, in which a coolant is circulated through a cavity in the bottom of the crucible, in the bottom plate of a crucible box, and/or in the crucible support block, has significantly larger crystal grain sizes compared to those produced using a similar process and apparatus in which no cavity is used to circulate a coolant beneath the crucible. As an example, a multicrystalline silicon ingot was prepared using the method and apparatus of the present invention, and as a comparative example, a multicrystalline silicon ingot was prepared using the comparative process with no cavity or circulating coolant provided. The ingots were cut with a wire saw, and grain boundaries were identified on a portion of an exposed cross-sectional surface using an optical scanner. The resulting images are shown in FIG. 9 (for the multicrystalline silicon produced using the method and apparatus of the present invention) and FIG. 10 (for the multicrystalline silicon produced using the comparative method and apparatus). Grain sizes were quantified, and a distribution was calculated using image analysis software. The statistical grain size distributions are shown in Table 1 below as well as graphically in FIG. 11

TABLE 1

| | FIG. 9 (example) | FIG. 10 (comparative) |
|---|---|---|
| Grain Area Range | % of Each Range | % of Each Range |
| <5 | 0.1 | 0.1 |
| 5-10 | 0.1 | 0.1 |
| 11-20 | 2.5 | 5.2 |
| 21-30 | 2.2 | 6.4 |
| 31-40 | 1.8 | 4.0 |
| 41-50 | 1.2 | 3.5 |
| 51-60 | 1.8 | 3.6 |
| 61-70 | 1.7 | 3.0 |
| 71-80 | 2.2 | 2.9 |
| 81-100 | 3.4 | 2.7 |
| 101-150 | 3.8 | 9.6 |
| 151-250 | 2.8 | 7.2 |
| 251-500 | 9.2 | 18.5 |
| >500 | 66.8 | 33.0 |

As the data shows, 66.8% of the multicrystalline silicon ingot produced by the method of the present invention had an average grain size greater than 500 mm² while only 33% of the comparative multicrystalline silicon ingot had a grain size in this range. Thus, multicrystalline silicon having significantly larger grain sizes is produced by the method and apparatus of the present invention. In addition, the crystal grains of the multicrystalline silicon produced in the method of the present invention were found to be substantially columnar from the bottom of the silicon ingot to the top, with the upper half and the lower half of the ingot both having large grain sizes. Furthermore, it was observed that the resulting orientations of the crystal grains were repeatable—that is, the same method with the same cavity provided in the same component produced crystalline materials having similar grain sizes and orientations. The resulting crystalline material, having larger overall grain sizes, would be expected to have better electrical and structural properties, thereby improving overall solar cell performance and enabling the cutting of thinner wafers.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A crystal growth apparatus comprising:
a hot zone surrounded by insulation;
a crucible box on a crucible support block in the hot zone, the crucible box having a bottom plate in thermal contact with the crucible support block; and
a crucible within the crucible box having a bottom in thermal contact with the bottom plate of the crucible box,
wherein the crucible support block, the bottom plate of the crucible box, or both the crucible support block and the bottom plate of the crucible box comprise at least one cavity configured to circulate at least one coolant therein.

2. The crystal growth apparatus of claim 1, wherein the crucible support block comprises at least one cavity configured to circulate at least one coolant therein.

3. The crystal growth apparatus of claim 2, wherein the cavity is in contact with the bottom plate of the crucible box.

4. The crystal growth apparatus of claim 1, wherein the bottom plate of the crucible box comprises at least one cavity configured to circulate at least one coolant therein.

5. The crystal growth apparatus of claim 4, wherein the cavity is in contact with the bottom of the crucible.

6. The crystal growth apparatus of claim 4, wherein the cavity is in contact with the crucible support block.

7. The crystal growth apparatus of claim 1, wherein the bottom of the crucible comprises at least one cavity in contact with the bottom plate of the crucible box, the cavity configured to circulate at least one coolant therein.

8. The crystal growth apparatus of claim 1, wherein the cavity comprises a separate inlet and outlet for circulating the coolant.

9. The crystal growth apparatus of claim 8, wherein the outlet is configured to exhaust the coolant into the hot zone.

10. The crystal growth apparatus of claim 1, wherein the coolant is gaseous.

11. The crystal growth apparatus of claim 10, wherein the gaseous coolant is argon or helium.

12. The crystal growth apparatus of claim 1, wherein the cavity is centrally positioned relative to the bottom of the crucible.

13. The crystal growth apparatus of claim 1, wherein the cavity has a circular cross-sectional shape in a direction parallel to the bottom of the crucible.

14. The crystal growth apparatus of claim 1, wherein the cavity forms a spiral cross-sectional shape in a direction parallel to the bottom of the crucible.

15. The crystal growth apparatus of claim 14, wherein the spiral has a varying path thickness.

16. The crystal growth apparatus of claim 14, wherein the spiral has a constant path thickness.

17. The crystal growth apparatus of claim 1, wherein the cavity has a concave cross-sectional shape in a direction perpendicular to the bottom and the crucible.

18. The crystal growth apparatus of claim 1, wherein the cavity has a convex cross-sectional shape in a direction perpendicular to the bottom of the crucible.

19. The crystal growth apparatus of claim 1, wherein the crucible contains at least one solid feedstock and no monocrystalline seed.

20. The crystal growth apparatus of claim 1, wherein the crucible contains silicon.

21. The crystal growth apparatus of claim 1, wherein the insulation is movable in a vertical direction relative to the crucible.

22. The crystal growth apparatus of claim 1, wherein the hot zone further comprises at least one heating element.

23. The crystal growth apparatus of claim 22, wherein the hot zone comprises a top heating element above the crucible and at least one side heating element surrounding the crucible.

24. A crystal growth apparatus comprising:
a hot zone surrounded by insulation, and
a crucible on a crucible support block in the hot zone, the crucible having a bottom in thermal contact with the crucible support block;
wherein the crucible support block, the bottom of the crucible, or both the crucible support block and the bottom of the crucible comprise at least one cavity configured to circulate at least one coolant.

25. The crystal growth apparatus of claim 24, wherein the crucible is silicon carbide, silicon nitride, or composites of silicon carbide or silicon nitride with silica.

26. A method of producing a crystalline material comprising the steps of:
i) placing a crucible contained in a crucible box onto a crucible support block in a hot zone of a crystal growth apparatus, the crucible box having a bottom plate in thermal contact with the crucible support block and the crucible containing solid feedstock and having a bottom in thermal contact with the bottom plate of the crucible box;
ii) heating the solid feedstock in the crucible to form a liquid feedstock melt;
iii) circulating at least one coolant through at least one cavity in the crucible support block, the bottom plate of the crucible box, or both the crucible support block and the bottom plate of the crucible box; and
iv) removing heat from the hot zone to form the crystalline material.

27. The method of claim 26, wherein the crystalline material is multicrystalline silicon having a plurality of crystal grains.

28. The method of claim 27, wherein the crystal grains of the multicrystalline silicon are columnar.

29. The method of claim 26, wherein the crucible contains at least one solid feedstock and no monocrystalline seed.

30. A method of producing a crystalline material comprising the steps of:
i) placing a crucible onto a crucible support block in a hot zone of a crystal growth apparatus, the crucible containing solid feedstock and having a bottom in thermal contact with the crucible support block;
ii) heating the solid feedstock in the crucible to form a liquid feedstock melt;
iii) circulating at least one coolant through at least one cavity in the crucible, the crucible support block, or both the crucible and the crucible support block; and
iv) removing heat from the hot zone to form the crystalline material.
